(19) United States
(12) Patent Application Publication
(10) Pub. No.: US 2026/0362797 A1
(43) Pub. Date: Nov. 12, 2026

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Kuo-Hsing Lee, Hsinchu County (TW); Sheng-Yuan Hsueh, Tainan City (TW); Chun-Hsien Lin, Tainan City (TW); Ting-Hsiang Huang, Tainan City (TW); Guan-Kai Huang, Tainan City (TW); Yao-Jhan Wang, Tainan City (TW)

(73) Assignee: UNITED MICROELECTRONICS CORP., Hsin-Chu City (TW)

(21) Appl. No.: 19/230,105

(22) Filed: Jun. 6, 2025

(30) Foreign Application Priority Data
May 7, 2025 (TW) 114117124

(51) Int. Cl. H10D 84/83; H10D 30/01; H10D 30/62; H10D 62/13; H10D 84/01

(52) U.S. Cl. CPC H10D 84/834; H10D 30/024; H10D 30/6211; H10D 62/151; H10D 84/0133; H10D 84/0149; H10D 84/0158; H10D 84/83125

(57) ABSTRACT

A method for fabricating a semiconductor device includes the steps of first providing a substrate having a first transistor region and a second transistor region, forming a shallow trench isolation (STI) around the first transistor region and the second transistor region, forming a gate structure extending from the first transistor region to the second transistor region, forming a first epitaxial layer adjacent to the gate structure on the first transistor region and a second epitaxial layer adjacent to the gate structure on the second transistor region, and then forming a trench in the STI between the first epitaxial layer and the second epitaxial layer.

### BACKGROUND OF THE INVENTION

### 1. Field of the Invention

The present invention relates to a method for fabricating a semiconductor device, and more particularly, to a method for forming a trench within shallow trench isolation (STI) between epitaxial layers of different transistor regions.

### 2. Description of the Prior Art

In the conventional semiconductor industry, polysilicon has been widely employed as the standard gate electrode material in semiconductor devices such as metal-oxide-semiconductor (MOS) transistors. However, with the continued scaling down of MOS transistor dimensions, traditional polysilicon gates have encountered critical challenges, including device performance degradation caused by boron penetration and the unavoidable depletion effect. These issues lead to an increase in the equivalent oxide thickness (EOT) and a reduction in gate capacitance, ultimately resulting in a decline in device drive capability. Consequently, the semiconductor industry has explored alternative gate electrode materials, particularly work function metals, as replacements for conventional polysilicon gates. These metal gate electrodes are designed to be compatible with high-k gate dielectrics, providing improved electrostatic control and enabling further device scaling.

In current metal gate transistor fabrication processes, electrical performance limitations remain, particularly in the input/output (I/O) and core regions, due to the predetermined gate dielectric thickness. A common issue arises during the removal of the sacrificial polysilicon gate, where wet cleaning processes frequently lead to epitaxial layer loss and the formation of voids in both regions. Therefore, optimizing and refining the existing metal gate process to resolve these defects has become a critical challenge in advanced semiconductor manufacturing

### SUMMARY OF THE INVENTION

According to an embodiment of the present invention, a method for fabricating a semiconductor device includes the steps of first providing a substrate having a first transistor region and a second transistor region, forming a shallow trench isolation (STI) around the first transistor region and the second transistor region, forming a gate structure extending from the first transistor region to the second transistor region, forming a first epitaxial layer adjacent to the gate structure on the first transistor region and a second epitaxial layer adjacent to the gate structure on the second transistor region, and then forming a trench in the STI between the first epitaxial layer and the second epitaxial layer.

According to another aspect of the present invention, a semiconductor device includes a substrate having a first transistor region and a second transistor region, a shallow trench isolation (STI) around the first transistor region and the second transistor region, a gate structure extending from the first transistor region to the second transistor region, a first epitaxial layer adjacent to the gate structure on the first transistor region, a second epitaxial layer adjacent to the gate structure on the second transistor region, and a trench in the STI between the first epitaxial layer and the second epitaxial layer.

According to yet another aspect of the present invention, a semiconductor device includes a substrate having a first transistor region and a second transistor region, a shallow trench isolation (STI) around the first transistor region and the second transistor region, and a gate structure extending from the first transistor region to the second transistor region. Preferably, a bottom surface of the gate structure directly on the STI between the first transistor region and the second transistor region includes a protruding portion.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-7 illustrate a method for fabricating a semiconductor device according to an embodiment of the present invention.

FIG. 8 illustrates a structural view of a semiconductor device according to an embodiment of the present invention.

FIG. 9 illustrates a structure of a semiconductor device fabricated in accordance with the process flow described in FIGS. 1-7 according to one embodiment of the present invention.

### DETAILED DESCRIPTION

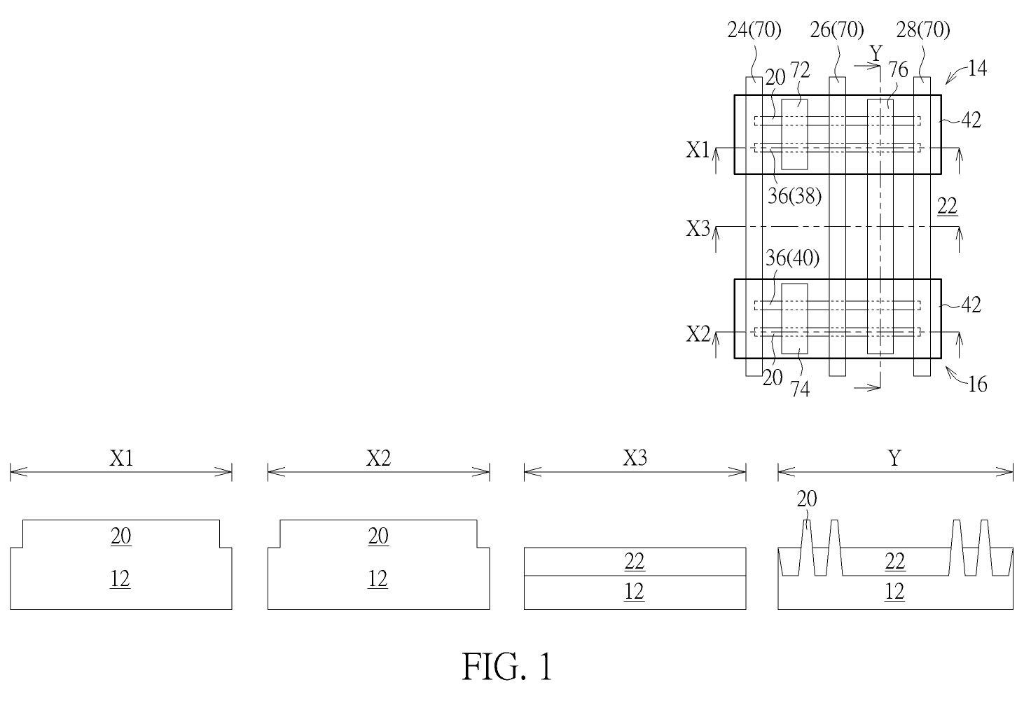

Referring to FIGS. 1-7, FIGS. 1-7 illustrate a method for fabricating a semiconductor device according to one embodiment of the present invention. The upper portions of FIGS. 1-7 depict top views of the semiconductor fabrication process, while the lower portions present corresponding cross-sectional views taken along directions X1, X2, X3, and Y as indicated in the top views. As shown in FIG. 1, a substrate 12 is first provided, such as a silicon substrate or a silicon-on-insulator (SOI) substrate. A first transistor region and a second transistor region are defined on the substrate 12. In this embodiment, the first and second transistor regions preferably correspond to transistors of different conductivity types. For example, the first transistor region may be a PMOS region 14 for forming PMOS transistors, while the second transistor region may be an NMOS region 16 for forming NMOS transistors. However, this is not a limitation of the invention.

Both the PMOS region 14 and the NMOS region 16 on the substrate 12 include at least one fin structure 20. The base of each fin structure 20 is surrounded by an insulating material, such as silicon dioxide, to form shallow trench isolation (STI) regions 22. It is noteworthy that although this embodiment uses the fabrication of non-planar fin field-effect transistors (FinFETs) as an example, the invention is not limited to such structures. The method is also applicable to conventional planar field-effect transistors, which also fall within the scope of the present invention.

According to an embodiment of the present invention, the fin-shaped structure 20 could be obtained by a sidewall image transfer (SIT) process. For instance, a layout pattern is first input into a computer system and is modified through suitable calculation. The modified layout is then defined in a mask and further transferred to a layer of sacrificial layer on a substrate through a photolithographic and an etching process. In this way, several sacrificial layers distributed with a same spacing and of a same width are formed on a substrate. Each of the sacrificial layers may be stripe-shaped. Subsequently, a deposition process and an etching process are carried out such that spacers are formed on the sidewalls of the patterned sacrificial layers. In a next step, sacrificial layers can be removed completely by performing an etching process. Through the etching process, the pattern defined by the spacers can be transferred into the substrate underneath, and through additional fin cut processes, desirable pattern structures, such as stripe patterned fin-shaped structures could be obtained.

Alternatively, the fin-shaped structure 20 could also be obtained by first forming a patterned mask (not shown) on the substrate, 12, and through an etching process, the pattern of the patterned mask is transferred to the substrate 12 to form the fin-shaped structure 20. Moreover, the formation of the fin-shaped structure 20 could also be accomplished by first forming a patterned hard mask (not shown) on the substrate 12, and a semiconductor layer composed of silicon germanium is grown from the substrate 12 through exposed patterned hard mask via selective epitaxial growth process to form the corresponding fin-shaped structure 20. These approaches for forming fin-shaped structure 20 are all within the scope of the present invention.

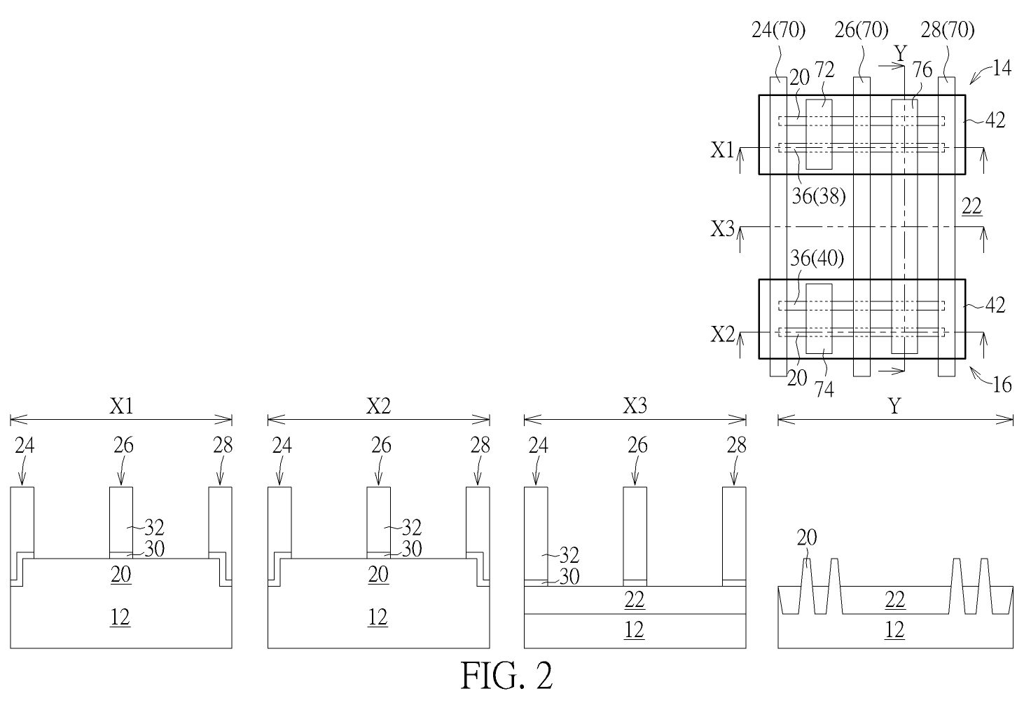

Next, as illustrated in FIG. 2, gate structures 24, 26, and 28 or dummy gates may be respectively formed over the substrate 12 in the PMOS region 14 and NMOS region 16. In this embodiment, the gate structures 24, 26, and 28 are preferably formed by sequentially depositing a gate dielectric layer 30, a gate material layer 32, and an optional hard mask layer (not shown) over the substrate 12. A patterned resist (not shown) is then used as a mask to perform a pattern transfer process, which involves either a single-step or multi-step etching procedure to selectively remove portions of the gate material layer 32 and gate dielectric layer 30. Afterward, the patterned resist is stripped, resulting in the formation of at least one gate structure 24, 26, and 28 over the fin structures 20 in both the PMOS and NMOS regions. Each gate structure includes a patterned gate dielectric layer 30 and a patterned gate material layer 32. In this embodiment, the gate dielectric layer 30 may include silicon dioxide and the gate material layer 32 may include polysilicon; however, the invention is not limited to these materials.

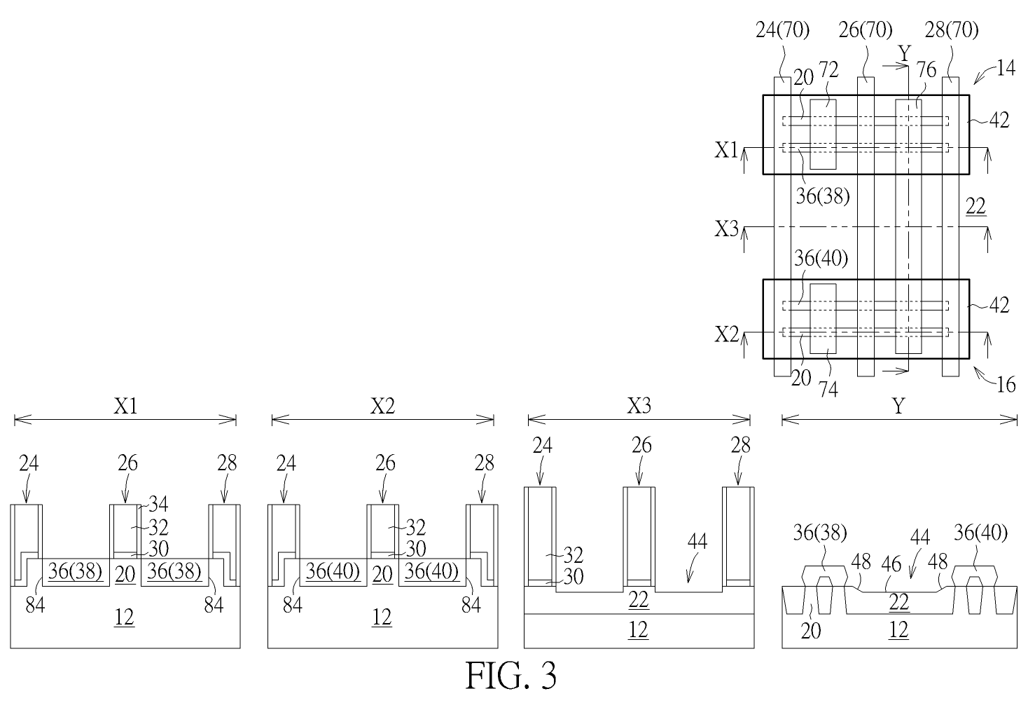

Next, as shown in FIG. 3, at least one spacer 34 is formed on the sidewalls of each gate structure 24, 26, and 28 and source/drain regions 36 and/or epitaxial layers 38 and 40 are then formed in the fin-shaped structures 20 and/or substrate 12 adjacent to both sides of the spacers 34. Optionally, a metal silicide layer (not shown) may be formed on the surface of the source/drain regions 36 and/or the epitaxial layers 38 and 40. In this embodiment, the spacer 34 may be a single-layer spacer or a composite spacer. For example, it may include an offset spacer (not shown) and a main spacer (not shown) and the spacer 34 may be made of a material selected from the group consisting of silicon oxide, silicon nitride (SiN), silicon oxynitride (SiON), and silicon carbonitride (SiCN), but is not limited thereto. The source/drain regions 36 and epitaxial layers 38 and 40 may contain different dopants or materials depending on the conductive type of the transistor being fabricated. For instance, the source/drain region 36 in the PMOS region 14 may be doped with p-type dopants and the epitaxial layer 38 may include silicon-germanium (SiGe). The source/drain region 36 in the NMOS region 16 on the other hand may be doped with n-type dopants and the epitaxial layer 40 may include silicon-phosphide (SiP).

In greater detail, during the formation of the epitaxial layers 38 and 40 in the PMOS region 14 and NMOS region 16 at this stage, it is preferable to first form a patterned mask (not shown), such as a patterned resist that covers most of the area between the PMOS region 14 and NMOS region 16. This patterned mask includes two openings 42 that expose portions of the fin-shaped structures 20 and gate structures 24, 26, 28 located in the PMOS region 14 and in the NMOS region 16, as seen in the top view of the upper part of FIG. 3. Using the patterned mask as an etching mask, one or more etching processes are carried out to remove portions of the fin-shaped structures 20 on both sides of the gate structures 24, 26, 28 in the PMOS region 14 and the NMOS region 16, thereby forming recesses 84. Subsequently, one or more epitaxial growth processes are performed to respectively form an epitaxial layer 38 in the PMOS region 14 and an epitaxial layer 40 in the NMOS region 16. Preferably, the epitaxial layer 38 in the PMOS region 14 includes silicon-germanium (SiGe) while the epitaxial layer 40 in the NMOS region 16 preferably includes silicon-phosphide (SiP).

It is worth noting that, due to the combined effect of the patterned mask coverage and the shadow effect, the etching process described above in this embodiment not only removes portions of the fin-shaped structures 20 on both sides of the gate structures 24, 26, 28 within the openings 42, but also partially removes the gate structures 24, 26, 28 themselves within the openings 42. However, the gate structures 24, 26, 28 outside the openings 42 remain unaffected. As a result, the top surfaces of the gate structures 24, 26, 28 along the X1 and X2 directions are slightly lower than those along the X3 direction.

In addition, during the aforementioned etching process used to remove portions of the fin-shaped structures 20 on both sides of the gate structures 24, 26, 28 within the openings 42, it is also preferable to simultaneously remove part of the shallow trench isolation (STI) 22 outside the openings 42, particularly the STI 22 located between the PMOS region 14 and the NMOS region 16 to form a trench 44. As observed in the cross-sectional views along the X3 and Y directions in FIG. 3, the formation of trench 44 preferably results in the top surface of the STI 22 on both sides of the gate structures 24, 26, 28 in the X3 direction being slightly lower than that of the STI 22 directly beneath the gate structures 24, 26, 28. In the Y direction, the top surface of the STI 22 is preferably slightly lower than the bottom surface of the adjacent epitaxial layers 38, 40 or lower than the top surface of the STI 22 beneath those epitaxial layers 38, 40. In greater detail, due to the slight recess formed beneath trench 44, the top surface of the STI 22 at the bottom of the trench 44 includes a flat or planar surface 46 and two inclined sidewalls 48 that extend laterally from both sides toward the epitaxial layers 38 and 40 in the PMOS region 14 and NMOS region 16, respectively.

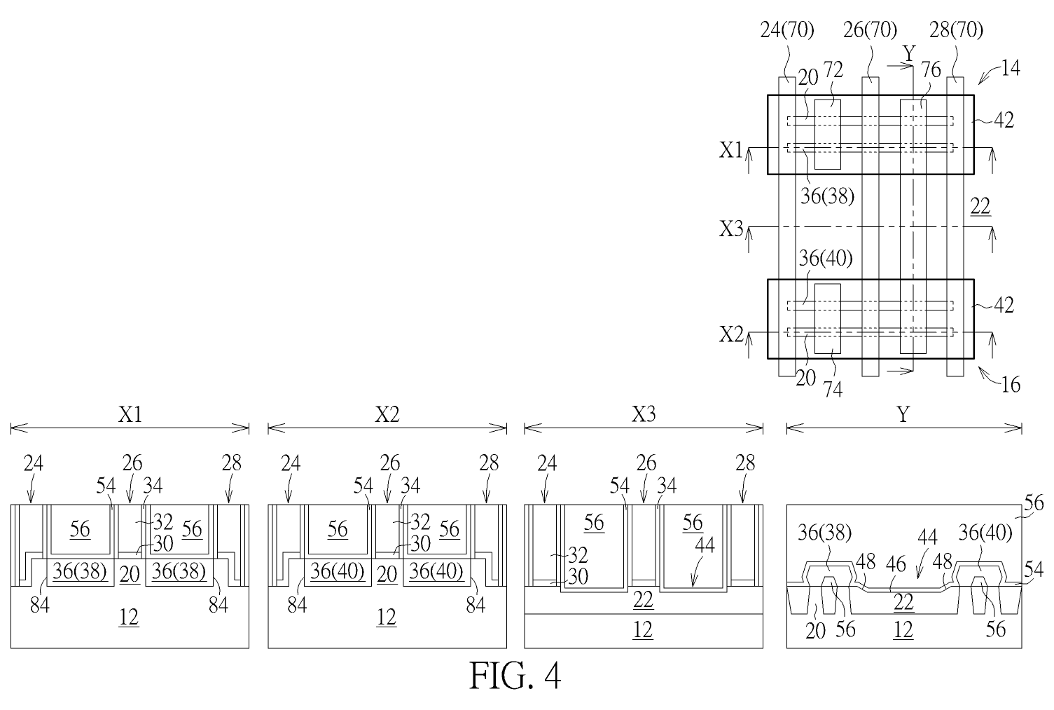

Next, as shown in FIG. 4, an optional contact etch stop layer (CESL) 54 composed of silicon nitride may be formed over the substrate 12 and covering the gate structures 24, 26, and 28, and then an interlayer dielectric (ILD) layer 56 is deposited over the CESL 54. Subsequently, a planarizing process such as chemical mechanical polishing (CMP) is performed to remove portions of the ILD layer 56 and the CESL 54, thereby exposing the gate material layer 32 made of polysilicon. This process results in the top surfaces of the gate material layers 32 in both the PMOS region 14 and NMOS region 16 being coplanar with the top surface of the ILD layer 56.

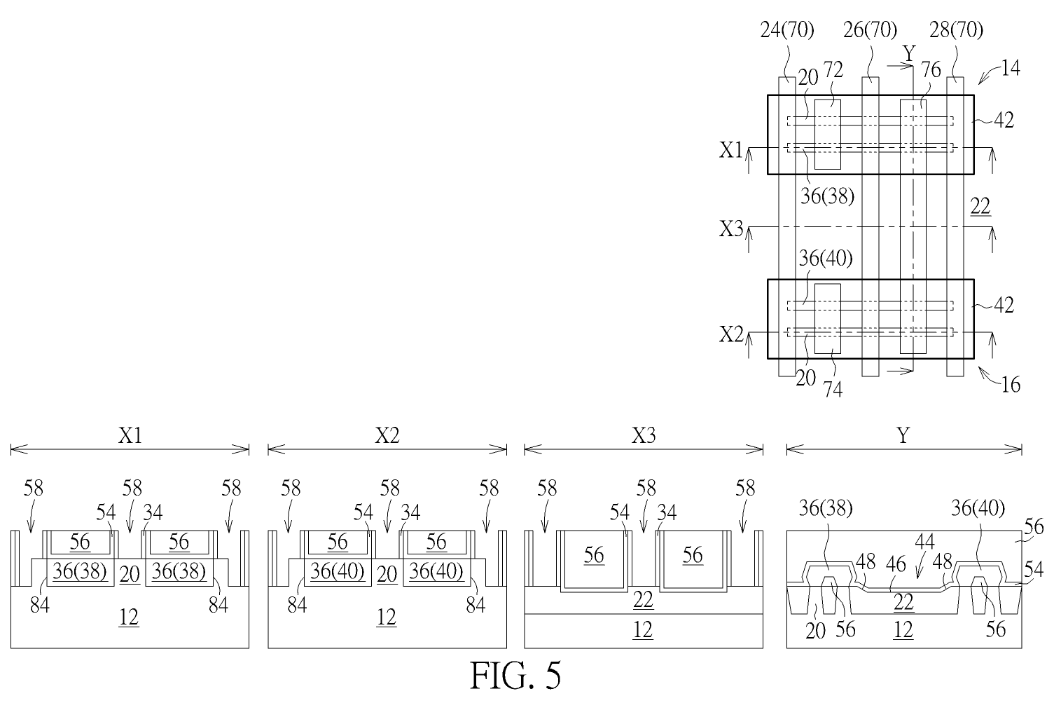

Next, as shown in FIG. 5, a replacement metal gate (RMG) process is conducted to transform the gate structures 24, 26, 28 into metal gates 70. For instance, a selective dry etching or wet etching process could be conducted by using etchant including ammonium hydroxide (NH₄OH) or tetramethylammonium hydroxide (TMAH) to remove the gate material layers 32 and gate dielectric layers 30 in the gate structures 24, 26, 28 in the PMOS region 14 and NMOS region 16 for forming recesses 58 in the ILD layer 56.

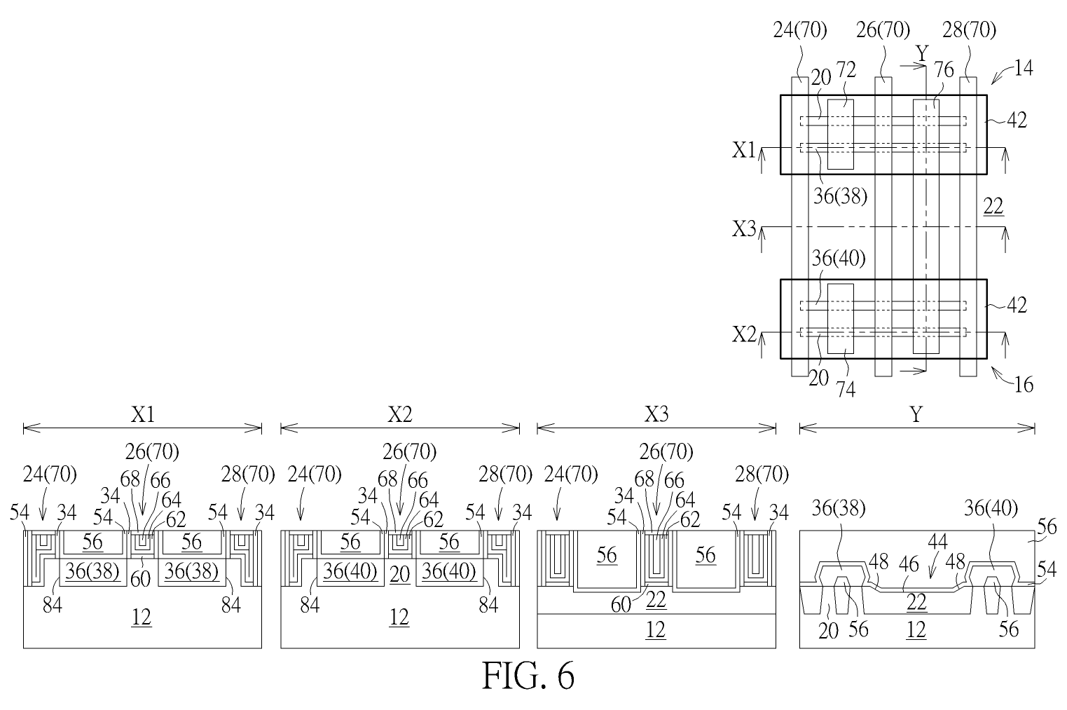

Next, as shown in FIG. 6, an oxide growth process such as a rapid thermal oxidation (RTO) process or an in-situ steam generation (ISSG) process is conducted to form a gate dielectric layer 60 made of silicon oxide in the recesses 58 in the PMOS region 14 and NMOS region 16. Next, a high-k dielectric layer 62, a work function metal layer 64, and a low resistance metal layer 66 are sequentially formed in the recesses 58, and a planarizing process such as CMP is conducted to remove part of the low resistance metal layer 66, part of the work function metal layer 64, and part of the high-k dielectric layer 62 for forming metal gates 70.

In this embodiment, the high-k dielectric layer 62 is preferably selected from dielectric materials having dielectric constant (k value) larger than 4. For instance, the high-k dielectric layer 62 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof. Preferably, the BBM layer 40 is selected from the group consisting of TiN and TaN, but not limited thereto.

In this embodiment, the work function metal layer 64 is formed for tuning the work function of the later formed metal gates to be appropriate in an NMOS or a PMOS. For an NMOS transistor, the work function metal layer 64 having a work function ranging between 3.9 eV and 4.3 eV may include titanium aluminide (TiAl), zirconium aluminide (ZrAl), tungsten aluminide (WAl), tantalum aluminide (TaAl), hafnium aluminide (HfAl), or titanium aluminum carbide (TiAlC), but it is not limited thereto. For a PMOS transistor, the work function metal layer 64 having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer 64 and the low resistance metal layer 66, in which the material of the barrier layer may include titanium (Ti), titanium nitride (TiN), tantalum (Ta) or tantalum nitride (TaN). Furthermore, the material of the low resistance metal layer 66 may include copper (Cu), aluminum (Al), titanium aluminum (TiAl), cobalt tungsten phosphide (CoWP) or any combination thereof.

Next, part of the high-k dielectric layer 62, part of the work function metal layer 64, and part of the low resistance metal layer 66 could be removed to form a recess (not shown), and a hard mask 68 could be formed in the recess so that the top surfaces of the hard mask 68 and ILD layer 56 are coplanar. The hard mask 58 could be selected from the group consisting of silicon oxide, silicon nitride, silicon oxynitride, and silicon carbon nitride.

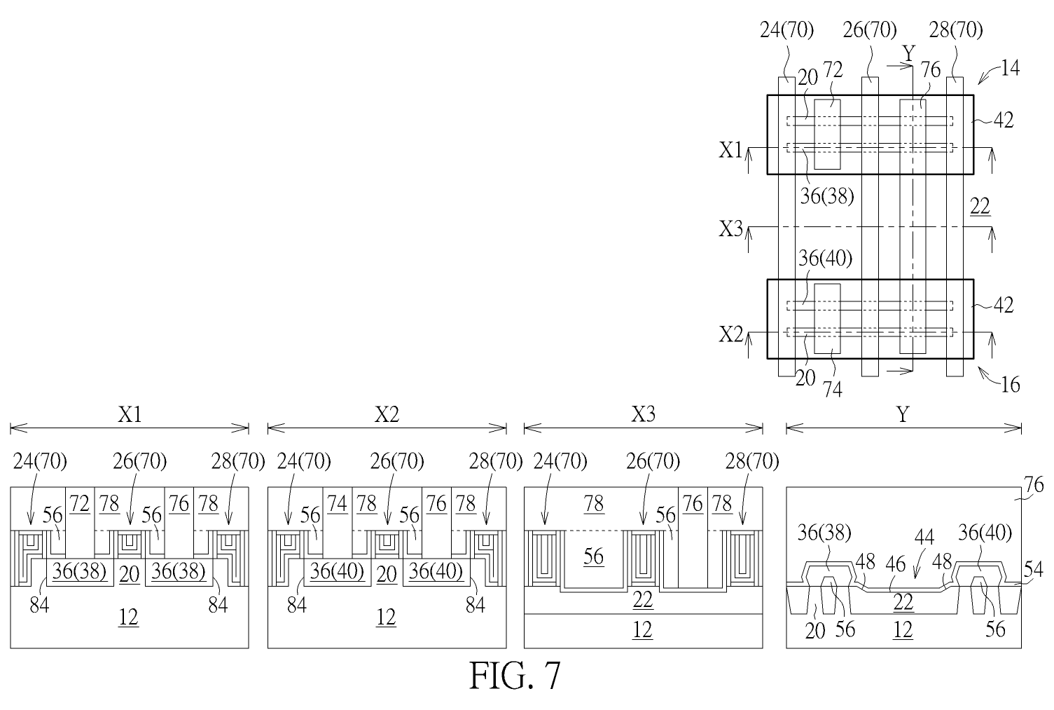

Next, as shown in FIG. 7, a contact plug formation could be conducted to form contact plugs 72, 74, 76 electrically connecting the source/drain regions 36 on the PMOS region 14 and NMOS region 16, in which the contact plugs 72, 74 in the X1 and X2 directions directly contact the source/drain regions 36 or epitaxial layers 38, 40 while the contact plugs 76 in the X3 direction directly contacts the CESL 54. In this embodiment, the formation of contact plugs 72, 74, 76 could be accomplished by first forming another ILD layer 78 on the ILD layer 56, removing part of the ILD layers 78, 56 and part of the CESL 54 to form contact holes (not shown), and then depositing a barrier layer (not shown) and a metal layer into the contact holes. A planarizing process such as CMP is then conducted to remove part of the metal layer, part of the barrier layer, and even part of the ILD layer 78 to form contact plugs 72, 74, 76 in the contact holes as the top surface of the contact plugs 72, 74, 76 is even with the top surface of the ILD layer 78. In this embodiment, the barrier layer is preferably selected from the group consisting of titanium (Ti), tantalum (Ta), titanium nitride (TiN), tantalum nitride (TaN), and tungsten nitride (WN) and the metal layer is preferably selected from the group consisting of aluminum (Al), titanium (Ti), tantalum (Ta), tungsten (W), niobium (Nb), molybdenum (Mo), and copper (Cu).

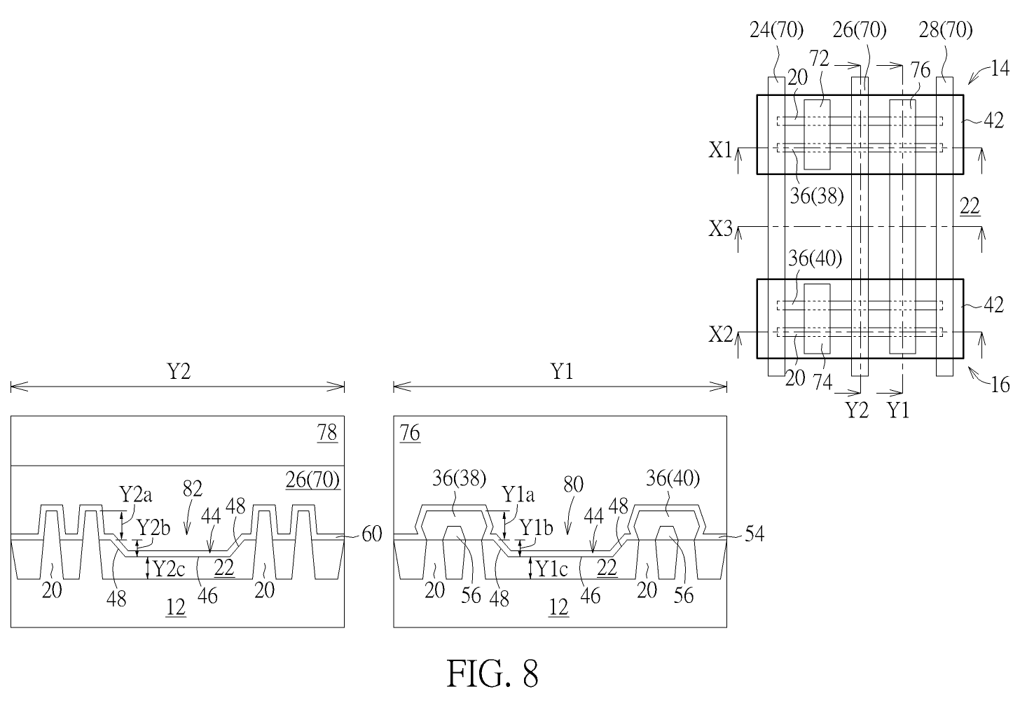

Referring to FIGS. 7-8, FIGS. 7-8 illustrate the structural schematic diagrams of a semiconductor device fabricated according to the process steps shown in FIGS. 1-7 in accordance with one embodiment of the present invention. In particular, the right half of FIG. 8 provides a top view of the semiconductor device while the left half presents cross-sectional views taken along the Y1 and Y2 directions as indicated in the top view. It should be noted that, for the sake of visual clarity, certain components of the gate structure 26 along the Y2 direction in FIG. 8 are intentionally omitted. Specifically, elements within the metal gate 70 such as the high-k dielectric layer 62, work function metal layer 64, low-resistance metal layer 66, and hard mask 68 are preferably not shown in the Y2-direction cross-section to simplify the illustration.

As shown in FIGS. 7-8, the semiconductor device primarily includes a STI 22 surrounding the PMOS region 14 and the NMOS region 16, gate structures 24, 26, 28 extending from the PMOS region 14 to the NMOS region 16, an epitaxial layer 38 disposed adjacent to the gate structures 24, 26, 28 in the PMOS region 14, an epitaxial layer 40 disposed adjacent to the gate structures 24, 26, 28 in the NMOS region 16, a trench 44 formed within the STI 22 between the epitaxial layers 38 and 40, a contact plug 72 disposed on one side of the gate structure 26 in the PMOS region 14, a contact plug 74 disposed on one side of the gate structure 26 in the NMOS region 16, and a contact plug 76 disposed on the opposite side of the gate structure 26 extending continuously from the PMOS region 14 to the NMOS region 16.

From the top view shown in the upper portion of FIG. 7 or the right half of FIG. 8, contact plugs 72 and 74 may have the same length, and the lengths of both contact plug 72 and contact plug 74 are shorter than that of contact plug 76. In the cross-sectional view along the Y1 direction, the epitaxial layers 38 and 40 have a height denoted as Y1a. The height from the flat surface 46 of the trench 44 in the STI 22 to the top surface of the fin structure 20 or equivalently to the bottom surface of the epitaxial layers 38 and 40 is denoted as Y1b. The height from the bottom surface of the STI 22 to the flat surface 46 of trench 44 is denoted as Y1c. Additionally, the bottom portion of contact plug 76 includes a protruding portion 80 located directly above the trench 44, in which the bottom surface of the protruding portion 80 conforms to the contour of the trench 44. In this embodiment, Y1a is preferably between 400 and 500 Angstroms or more preferably around 450 Angstroms, Y1b is preferably between 200 and 300 Angstroms or more preferably around 250 Angstroms, Y1c is preferably between 450 and 550 Angstroms or more preferably around 500 Angstroms. The width of the bottom surface of protruding portion 80 is preferably at least one time, two times, three times, four times, or even more than five times the width of each epitaxial layer 38 or 40. All of these configurations fall within the scope of the present invention.

Additionally, from the cross-sectional view along the Y2 direction, the bottom surface of the gate structure 26 located directly above the STI 22 between the PMOS region 14 and the NMOS region 16 also includes a protruding portion 82. The height from the surface of the substrate 12 on either side of the protruding portion 82 to the top surface of the fin-shaped structure 20 is defined as Y2a. The overall depth of the protruding portion 82 or the height from the bottom surface of the protruding portion 82 to the adjacent surface of the STI 22 is defined as Y2b. The height from the bottom surface of the STI 22 to the bottom surface of the protruding portion 82 (or the flat surface 46 of trench 44) is defined as Y2c. In this embodiment, Y2a is preferably between 400 and 500 Angstroms or more preferably around 450 Angstroms, Y2b is preferably between 50 and 150 Angstroms or more preferably around 100 Angstroms, and Y2c is preferably between 600 and 700 Angstroms or more preferably around 650 Angstroms. Similar to the protruding portion 80 at the bottom of contact plug 76, the bottom surface of the protruding portion 82 of gate structure 26 (or metal gate 70) preferably has a width greater than one, two, three, four, five, or even ten times the width of each of the epitaxial layers 38, 40 or fin-shaped structures 20. All such configurations fall within the scope of the present invention.

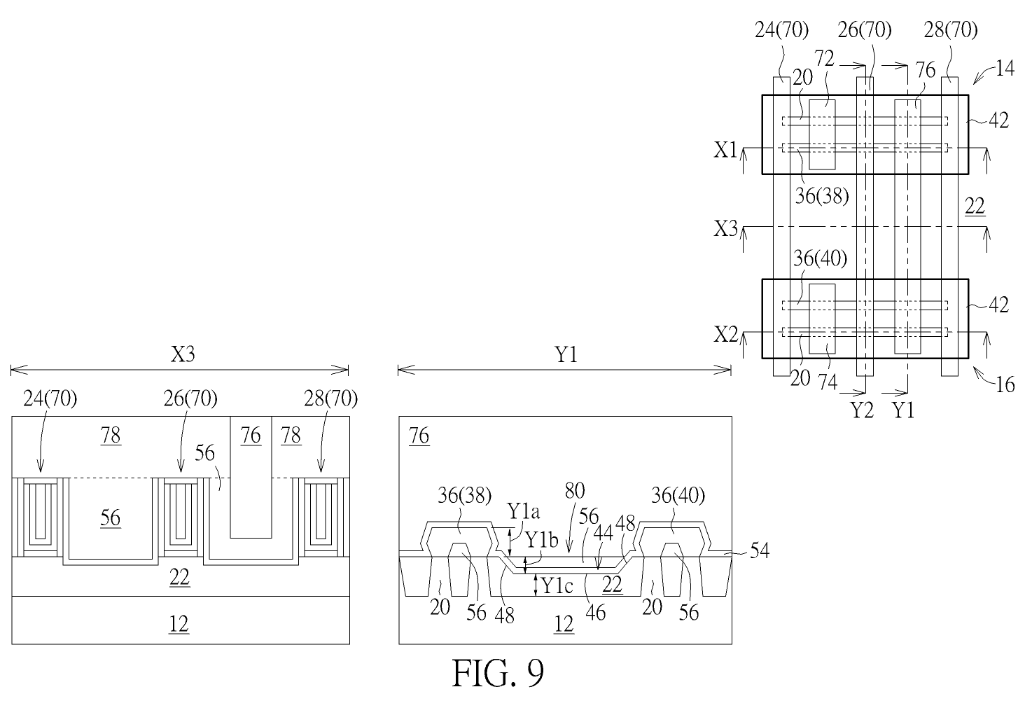

Referring to FIG. 9, which illustrates the structure of a semiconductor device fabricated in accordance with the process flow described in FIGS. 1-7 according to one embodiment of the present invention. The upper part of FIG. 9 shows a top view of the fabricated semiconductor device while the lower part presents cross-sectional views taken along the X3 and Y directions of the top view. As shown in FIG. 9, in contrast to the previous embodiment where the bottom of contact plug 76 directly contacts the CESL 54 while extending from the PMOS region 14 to the NMOS region 16, the present invention alternatively allows for retaining a portion of the interlayer dielectric (ILD) layer 56 within trench 44 during the formation of contact plug 76.

In this configuration, the top surface of the retained ILD layer 56 is approximately level with the surface of the substrate 12 on both sides of the trench 44. Consequently, once contact plug 76 is formed, the contact plug 76 may be suspended between the two gate structures 26 and 28 with its bottom and side surfaces fully surrounded by the ILD layer 56 as shown in the X3 direction cross-section or the bottom of the contact plug 76 may contact both the ILD layer 56 and the CESL 54 as shown in the Y direction cross-section. All such variations are within the scope of the present invention.

In summary, the present invention primarily involves first forming gate structures over the PMOS and NMOS regions, forming a patterned mask to cover most of the area between the PMOS region 14 and the NMOS region 16, and using the patterned mask as an etching mask to remove portions of the substrate on both sides of the gate structures to form recesses while simultaneously forming a trench 44 within a portion of the STI 22 between the PMOS and NMOS regions. Subsequently, epitaxial layers 40 are formed in the PMOS region 14 and NMOS region 16 via epitaxial growth processes. According to a preferred embodiment of the present invention, the trench formed at the boundary between the two transistors exhibits a relatively shallow depth. This helps improving the overall process window and preventing the subsequently formed metal interconnects from being placed too close to the substrate, which could otherwise adversely affect the performance of the device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a semiconductor device, comprising:
providing a substrate having a first transistor region and a second transistor region;
forming a shallow trench isolation (STI) around the first transistor region and the second transistor region;
forming a gate structure extending from the first transistor region to the second transistor region;
forming a first epitaxial layer adjacent to the gate structure on the first transistor region and a second epitaxial layer adjacent to the gate structure on the second transistor region; and
forming a trench in the STI between the first epitaxial layer and the second epitaxial layer.

2. The method of claim 1, further comprising:
forming a first recess adjacent to the gate structure on the first transistor region, a second recess adjacent to the gate structure on the second transistor region, and the trench in the STI;
forming the first epitaxial layer in the first recess and forming the second epitaxial layer in the second recess;
forming an interlayer dielectric (ILD) layer around the gate structure; and
performing a replacement metal gate (RMG) process to transform the gate structure into a metal gate.

3. The method of claim 2, further comprising:
forming a first contact plug adjacent to one side of the metal gate on the first transistor region;
forming a second contact plug adjacent to one side of the metal gate on the second transistor region; and
forming a third contact plug adjacent to another side of the metal gate extending from the first transistor region to the second transistor region.

4. The method of claim 3, wherein a bottom surface of the third contact plug comprises a protruding portion directly on the trench.

5. The method of claim 3, wherein a length of the first contact plug is less than a length of the third contact plug.

6. The method of claim 1, wherein a depth of the trench is less than a height of the first epitaxial layer.

7. A semiconductor device, comprising:
a substrate having a first transistor region and a second transistor region;
a shallow trench isolation (STI) around the first transistor region and the second transistor region;
a gate structure extending from the first transistor region to the second transistor region;
a first epitaxial layer adjacent to the gate structure on the first transistor region;
a second epitaxial layer adjacent to the gate structure on the second transistor region; and
a trench in the STI between the first epitaxial layer and the second epitaxial layer.

8. The semiconductor device of claim 7, further comprising:
a first contact plug adjacent to one side of the gate structure on the first transistor region;
a second contact plug adjacent to one side of the gate structure on the second transistor region; and
a third contact plug adjacent to another side of the gate structure extending from the first transistor region to the second transistor region.

9. The semiconductor device of claim 8, wherein a bottom surface of the third contact plug comprises a protruding portion directly on the trench.

10. The semiconductor device of claim 8, wherein a length of the first contact plug is less than a length of the third contact plug.

11. The semiconductor device of claim 7, wherein a depth of the trench is less than a height of the first epitaxial layer.

12. A semiconductor device, comprising:
a substrate having a first transistor region and a second transistor region;
a shallow trench isolation (STI) around the first transistor region and the second transistor region; and
a gate structure extending from the first transistor region to the second transistor region, wherein a bottom surface of the gate structure directly on the STI between the first transistor region and the second transistor region comprises a protruding portion.

13. The semiconductor device of claim 12, further comprising:
a first fin-shaped structure on the first transistor region;
a second fin-shaped structure on the second transistor region; and
the gate structure on the first fin-shaped structure and the second fin-shaped structure.

14. The semiconductor device of claim 13, wherein the protruding portion is between the first fin-shaped structure and the second fin-shaped structure.

15. The semiconductor device of claim 12, further comprising a trench in the STI between the first transistor region and the second transistor region.

16. The semiconductor device of claim 15, wherein protruding portion is directly on the trench.

17. The semiconductor device of claim 12, wherein the gate structure comprises a metal gate.
